(19) United States
(12) Patent Application Publication
(10) Pub. No.: US 2008/0212287 A1
(43) Pub. Date: Sep. 4, 2008

(54) SEMICONDUCTOR PACKAGE STRUCTURE WITH BURIED ELECTRONIC DEVICE AND MANUFACTURING METHOD THEROF

(76) Inventors: Che-Kun Shih, Kaohsiung City (TW); Yung-Hui Wang, Kaohsiung City (TW)

Correspondence Address: Muncy, Geissler, Olds & Lowe, PLLC, P.O. BOX 1364, FAIRFAX, VA, 22038-1364, US

(21) Appl. No.: 12/040,634

(22) Filed: Feb. 29, 2008

(30) Foreign Application Priority Data
Mar. 1, 2007 (TW) 96107040

(51) Int. Cl. H05K 1/11; H05K 3/40

(52) U.S. Cl. 361/714; 361/761; 29/852

(57) ABSTRACT

A semiconductor package structure and manufacturing method thereof are provided, wherein the semiconductor package structure comprises a multi-layer circuit board, an electronic device and a slug. The multi-layer circuit board has at least one via hole, and the electronic device having a upper surface is buried in the multi-layer circuit board, wherein a portion of the upper surface is connected with the via hole. The slug is set in the via hole. One end of the slug is in contact with the upper surface of the electronic device and the other end of the slug is exposed out of the multi-layer circuit board through the via hole.

### RELATED APPLICATIONS

This application claims priority to Taiwan Application Serial Number 96107040, filed Mar. 1, 2007, which is herein incorporated by reference.

### FIELD OF THE INVENTION

The present invention relates to a semiconductor package structure and the manufacturing method thereof, and more particularly relates to a semiconductor package structure with an electronic device buried therein and the manufacturing method thereof.

### BACKGROUND OF THE INVENTION

Semiconductor package structures with a buried electronic device is a kind of packaging structure that has multiple stacked layers of substrate made of special dielectric material or organic glass-fiber to bury at least one electronic device therein.

In practical application, various substrates with diverse resistances and dielectric coefficients are selected to bury an electronic device, such as an active or passive component (i.e. a capacitor, a resistor or a high frequency transmission line) therein in depending upon characters of the integrity circuit (IC) designed in a semiconductor package, so as to improve the performance of the semiconductor package by virtue of involving more IC on limited space provided by the selected substrate. Since the active (passive) components are buried and interconnected to the IC, less bonding processes and bonding area are required for the bonding of the active (passive) components on the IC. Thus the manufacturing cost of the semiconductor package structure can be decreased.

However, it is hard to dissipate heat generated by the IC and the active (passive) components buried in the multiple stacked substrates, and heat accumulated in the semiconductor package structure may decrease the total performance of the semiconductor package structure and even create a hazard for the devices involved therein. The problems may get worse while the IC integrity is getting more and more increased.

### SUMMARY OF THE INVENTION

Therefore, it is desirable to provide an advanced semiconductor package structure having a slug to resolve the problems due to heat accumulation as long as the number of the active (passive) components buried in the multiple stacked substrates and the IC integrity of the semiconductor package structure is increased.

One aspect of the present invention is to provide a semiconductor package structure comprising a multi-layer circuit board, an electronic device and a slug. The multi-layer circuit board has at least one via hole, and the electronic device with a upper surface is buried in the multi-layer circuit board, wherein a portion of the upper surface is exposed from the via hole. The slug is set in the via hole. One end of the slug is in contact with the upper surface of the electronic device and the other end of the slug is exposed out of the multi-layer circuit board through the via hole.

Another aspect of the present invention is to provide a method for manufacturing a semiconductor package structure. The method comprises steps as following: first a multi-layer circuit board having at least one electronic device buried therein is provided, wherein the electronic device has a upper surface. At lest one via hole is subsequently formed on the multi-layer circuit board, whereby a portion of the electronic device is exposed via hole the via hole. A heat-dissipating material is then filled into the via hole to form a slug, wherein one end of the slug is in contact with the upper surface of the electronic device and the other end of the slug extends out from the via hole set on the multi-layer circuit board.

In accordance with above descriptions, the features of the present invention is to bury at least one electronic device in an multi-layer circuit layer for allowing more IC to be formed on the multi-layer circuit board, and then to form at least one via hole on a surface of the multi-layer circuit board to expose a portion of the surface of the electronic device, whereby the heat generated by the IC and the electronic device can be dissipated via a slug that is set in and extends out from the via hole.

Accordingly, a semiconductor package structure that has at least one electronic device buried therein can increasingly improve its heat-dissipating efficiency by applying the aforementioned features of the present invention, whereby the prior problems of heat accumulation which results the buried device burn out can be resolved.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A illustrates a cross section view of a semiconductor package structure 100 in accordance with a first preferred embodiment of the present invention.

FIG. 1B illustrates a top view of a semiconductor package structure 100′ in accordance with another embodiment of the present invention.

FIG. 2 illustrates a processing flow chart for manufacturing the semiconductor package structure 100 of FIG. 1A.

### DETAILED DESCRIPTION OF THE PREFERRED EMBODIMENT

The foregoing aspects and many of the attendant advantages of this invention will become more readily appreciated as the same becomes better understood by reference to the following preferred embodiments of semiconductor package structure that has a slug and the manufacturing methods thereof.

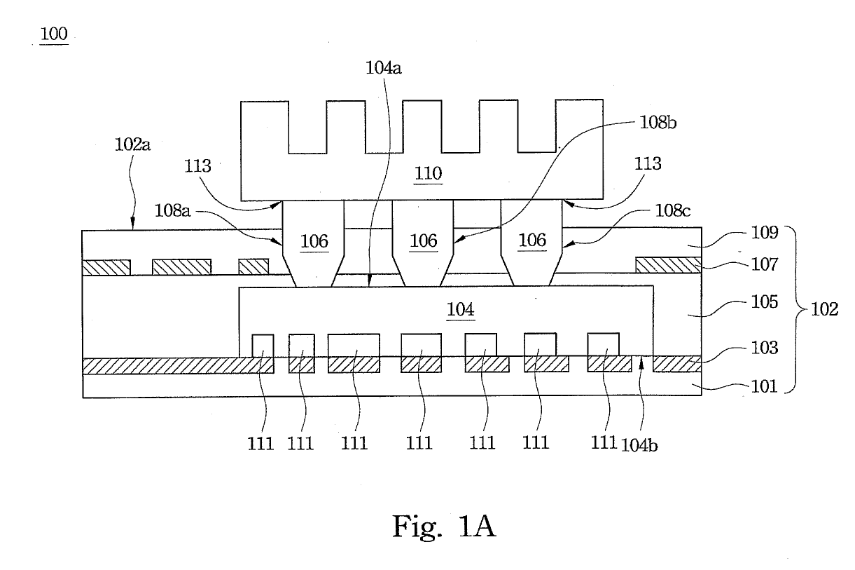

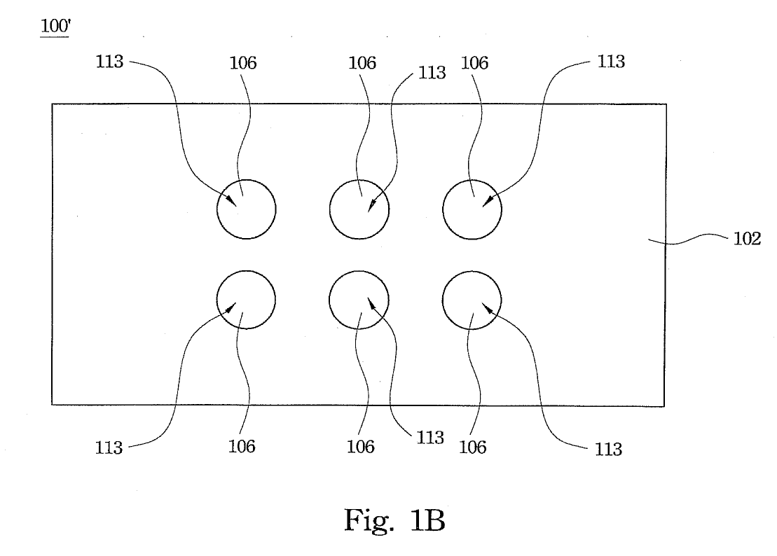

Please refer to FIG. 1A, FIG. 1A illustrates a cross section view of a semiconductor package structure 100 in accordance with a first preferred embodiment of the present invention.

The semiconductor package structure 100 comprises a multi-layer circuit board 102, an electronic device 104 and a slug 106.

The multi-layer circuit board 102 is an interlayer circuit board comprising a plurality of printed circuit boards (PCB) stacked together, wherein the multi-layer circuit board 102 has at least one via hole, such as via holes 108a, 108b and 108c, extending from a surface 102a of the multi-layer circuit board 102 towards the inside thereof. The electronic device 104 is buried in the multi-layer circuit board 102. In some embodiments of the present invention, the electronic device 104 is an active component, such as a transistor. However, in some other embodiments of the present invention, the electronic device is a passive component, such as a resistor or a capacitor.

In the present embodiment, multi-layer circuit board 102 comprises a bottom lamination layer 101, a first conductive layer 103, a dielectric layer 105, a second conductive layer 107 and a upper lamination layer 109, wherein the bottom lamination layer 101 and the upper lamination layer 109 are made of dielectric material used to protect the semiconductor package structure 100.

The first conductive layer 103 is set on the bottom lamination layer 101. In a preferred embodiment of the present invention, the first conductive layer 103 is a patterned copper layer formed on the bottom lamination layer 101. The formation of the first conductive layer 103 comprises the following steps: First an electroplating process, a spin coating process or an imprinting process forms a copper layer on the bottom lamination layer 101. The copper layer is then patterned to form the first conductive layer 103.

The dielectric layer 105 set on the first conductive layer 103 is a core layer made by a dielectric material having a thickness allowing at least one electronic device 104 (such as an active component, a passive component or the combination thereof) buried therein.

The second conductive layer 107 is preferably a patterned copper layer, wherein an electroplating process, a spin coating process or an imprinting process forms the copper layer on the dielectric layer 105, and then is patterned. After the forming of the second conductive layer 107, the upper lamination layer 109 is blanketed over the second conductive layer 107.

Of note that the aforementioned embodiments are just illustrative, any person skilled in the art may modify the described embodiments to improve the performance of the semiconductor package structure 100 within the spirit and scope of the present invention. For example the PCB layers stacked in the multi-layer circuit board 102 may be increased in a practical application to improve the permittivity of the semiconductor package structure 100.

Please refer to FIG. 1A again, the electronic device 104 comprises a plurality of pads 111 set on a upper surface 104a of the electronic device 104 or on a lower surface 104b of the electronic device 104 or on both of them. For example in some embodiments of the present invention, the pads 111 are either set on the upper surface 104a or the lower surface 104b of the electronic device 104; in some other embodiments, some of the pads 111 maybe set on the lower surface 104b of the electronic device 104 and the others are set on the upper surface 104a. The pads 111 set on the electronic device 104 either electrically connect to the first conductive layer 103 or to the second conductive layer 107 via electrical contacts (not shown).

In the present embodiment of the present invention, all of the pads 111 are set on the lower surface 104b which serves as an active surface of the electronic device 104 used to electrically connect to the first conductive layer 103; the upper surface of the electronic device 104 which serves as a rear surface has no any pad set thereon; and portion of the first surface 104a of the electronic device 104 is exposed from the multi-layer circuit board 102 via the via holes 108a, 108b and 108c prior the slug 106 is set in the via holes 108a, 108b and 108c.

The slug 106 that is a heat sink made of metal material, or nonmetal material set in the via holes 108a, 108b and 108c. In some preferred embodiments the slug 106 is a structure made of copper, wherein one end of the structure is contact with the upper surface 104a of the electronic device 104 that is exposed via the via holes 108a, 108b and 108c; the other end of the structure extends outwards the via holes 108a, 108b and 108c that are formed on the surface 102a of the multi-layer circuit board 102.

In the preferred embodiment of the present invention, the semiconductor package structure further comprises a heat-dissipating fin 110 connected to the end of the slug 106 extends out from the via holes 108a, 108b and 108c, wherein the heat-dissipating fin 110 protrudes beyond the surface 102a of the multi-layer circuit board 102 to expose itself to the air to improve the heat dissipation.

FIG. 1B illustrates a top view of a semiconductor package structure 100′ in accordance with second embodiment of the present invention. The difference between FIG. 1A and FIG. 1B is that FIG. 1A further comprises a heat-dissipating fin 110. In some embodiments of the present invention, the end of the slug 106 extends out from the via holes 108a, 108b and 108c and have a contact surface 113 that conforms with the surface 102a of the multi-layer circuit board 102. In some other embodiments of the present invention, the end of the slug 106 extends out from the via holes 108a, 108b and 108c protrudes beyond the surface 102a of the multi-layer circuit board 102. The shape and the size of the slug 106 may vary depending on the shape and the size of the via holes 108a, 108b and 108c. For example the slug 106 is a heat sink set in the via holes 108a, 108b and 108c, and the portion of the slug 106 set in the via holes 108a, 108b and 108c is shaped as a pillar or a cone in associate with the shape and the size of the via holes 108a, 108b and 108c.

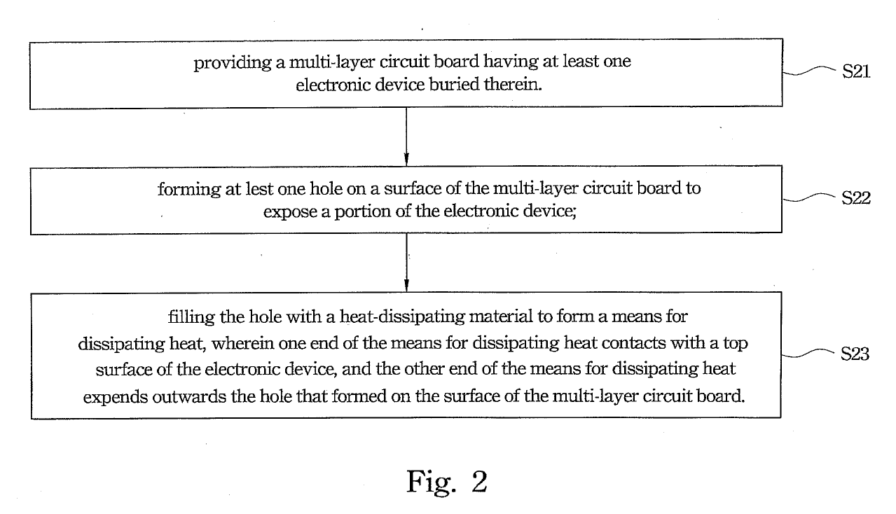

Please refer to FIG. 2, FIG. 2 illustrates a processing flow chart for manufacturing the semiconductor package structure 100 of FIG. 1A. The formation of the semiconductor package structure 100 comprises steps as follows:

First a multi-layer circuit board 102 having at least one electronic device 104 buried therein is provided, wherein the electronic device has an upper surface 104a (Referring to step S21). A plurality of via holes, such as via holes 108a, 108b and 108c, are formed on the surface 102a of the multi-layer circuit board 102 to expose a portion of the upper surface 104a of the electronic device 104 (Referring to step S22). The via holes 108a, 108b and 108c subsequently are filled with a heat-dissipating material (such as copper) to form the slug 106, wherein one end of the slug 106 is in contact with the upper surface 104a of the electronic device 104 and the other end of the slug 106 extends outwards the via holes 108a, 108b and 108c that are formed on the surface of the multi-layer circuit board 102 (Referring to step S23). In some preferred embodiments of the present invention, heat-dissipating material is electroplated into the via holes 108a, 108b and 108c to form the slug 106. Furthermore, a heat-dissipating fin 110 is connected on the end of the slug 106 extends out from the via holes 108a, 108b and 108c, wherein the heat-dissipating fin 110 protrudes beyond the surface 102a of the multi-layer circuit board 102 to expose itself to the air for improving the heat dissipation of the slug 106.

In accordance with above descriptions, the features of the present invention is to bury at least one electronic device in an interlayer circuit layer for allowing more IC formed on the multi-layer circuit board, and then to form at least one via hole on the multi-layer circuit board for exposing portion surface of the electronic device, whereby heat generated by the IC and the electronic device can be dissipated via slug that is formed in the via hole. In the preferred embodiment of the present invention one end of the slug is in contact with the upper surface of the electronic device and the other end of the slug extends outwards the via hole that is formed on the surface of the multi-layer circuit board. Accordingly, heat-dissipating efficiency of a semiconductor pack(age structure that has at least one electronic device buried therein can be increasingly improved by applying the aforementioned features of the present invention, and the prior problems of heat accumulation which results the buried device burn out can be resolved.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A semiconductor package structure, comprising:
a multi-layer circuit board having at least one via hole formed on a surface of the multi-layer circuit board;
an electronic device buried in the multi-layer circuit board, wherein the electronic device has a upper surface, and a portion of the upper surface is connected with the via hole; and
a slug set in the via hole, wherein one end of the slug is in contact with the tipper surface of the electronic device and the other end of the slug is exposed out of the multi-layer circuit board through the via hole.

2. The semiconductor package structure in accordance with claim 1, wherein the multi-layer circuit board comprises:
a lower lamination layer;
a first conductive layer set on the lower lamination layer;
a dielectric layer set on the first conductive layer;
a second conductive layer set on the dielectric layer; and
a upper lamination layer blanketed over the second conductive layer.

3. The semiconductor package structure in accordance with claim 1, wherein the slug is a heat sink made of metal material or nonmetal material.

4. The semiconductor package structure in accordance with claim 1, wherein the slug set in the via hole is shaped as a pillar or a cone.

5. The semiconductor package structure in accordance with claim 3, wherein the heat sink is a copper structure set in the via hole.

6. The semiconductor package structure in accordance with claim 1, wherein the upper surface serves as a rear surface of the electronic device.

7. The semiconductor package structure in accordance with claim 1, wherein the upper surface has no any pad set thereon.

8. The semiconductor package structure in accordance with claim 1, wherein the slug is exposed out of an end of multi-layer circuit board, and one surface of the slug is coplanar with one surface of the multi-layer circuit board.

9. The semiconductor package structure in accordance with claim 1, wherein the slug is exposed out of an end of multi-layer circuit board, and the slug protrudes out of the surface of the multi-layer circuit board.

10. The semiconductor package structure in accordance with claim 1, further comprising a heat-dissipating fin connected to the end of the slug that is exposed out of an end of multi-layer circuit board.

11. A method for manufacturing a semiconductor package structure comprising:
providing a multi-layer circuit board having at least one electronic device buried therein;
forming at least one via hole on a surface of the multi-layer circuit board to expose a portion of the electronic device;
filling the via hole with a heat-dissipating material to form a slug, wherein one end of the slug contacts with a upper surface of the electronic device, and the other end of the slug extends outwards the via hole that formed on the surface of the multi-layer circuit board.

12. The method in accordance with claim 11, wherein the slug is formed by a electroplate process to fill the heat-dissipating material into the via hole.

13. The method in accordance with claim 11, further comprising the step of connecting a heat-dissipating fin to the end of the slug that is exposed out of an end of multi-layer circuit board.
